(19) United States
(12) Patent Application Publication
(10) Pub. No.: US 2010/0285636 A1
(43) Pub. Date: Nov. 11, 2010

(54) MANUFACTURING METHOD OF A PACKAGING STRUCTURE OF ELECTRONIC COMPONENTS

(75) Inventor: HUAI-TE CHEN, TAOYUAN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: ACSIP TECHNOLOGY INC., TAOYUAN COUNTY (TW)

(21) Appl. No.: 12/492,572

(22) Filed: Jun. 26, 2009

(30) Foreign Application Priority Data
May 11, 2009 (TW) 098115516

(51) Int. Cl. H01L 21/82

(52) U.S. Cl. 438/113; 257/E21.602

(57) ABSTRACT

A manufacturing method of a packaging structure of electronic components includes the steps of: providing a substrate including a plurality of electronic components; covering the electronic components disposed on the substrate with a molding body; forming a plurality of pre-cut grooves on the molding body so as to define a plurality of molding units on the molding body; forming an electromagnet barrier layer covering the molding units on the molding units and the pre-cut grooves; and cutting along at least one of the pre-cut grooves deeply down to break the substrate so as to form separately a plurality of packaging structures of the electronic components.

### FIELD OF THE INVENTION

The present invention relates to a manufacturing method of a packaging structure of electronic components, and particularly relates to a manufacturing method of a packaging structure of electronic components that is able to block the electromagnetic interference (EMI).

### BACKGROUND OF THE INVENTION

In circuit design, leads, circuit boards, and/or various electronic components can generate electromagnetic waves which may affect the overall performance of the circuit. Such a phenomenon is the so-called electromagnetic interference (EMI). In practice, the EMI is unable to be completely eliminated. Actually, problems caused by the EMI can only be minimized by excellent circuit design and route design.

In related art, it is common to shield an electronic component by a metal housing which forms a conducting barrier for blocking possible electromagnetic waves so as to reduce the effect of the EMI.

Amid the trend of miniaturization, high frequency, and higher density of distribution in electronic design, the problems of EMI can only become more troublesome and hard to be handled. Taking mobile communication products for example, it is the trend to integrate various wireless modules such as Wi-Fi, Bluetooth, Global Positioning System (GPS), etc. into one single module. However, the application of the aforesaid three modules in a single tiny substrate or product can only make the EMI problem (mainly by interacting) more severely. It can be foreseen that, in the modern communication product, interacting EMI problem among built-in modules inside an individual system become a real issue.

It is easy to see that the conventional metal housing, which is applied to shield a system or an equipment, is no more relevant to solve the interacting EMI problem inside a single system or module, which provides only extremely limited and irregular space for anti-EMI construction. Besides, it is also technically difficult and also expensive to manufacture tiny metal housings for individual elements in the same electronic product so as to reduce internal EMIs from those different wireless modules.

Therefore, the need for a manufacturing method of a packaging structure of electronic components that can reduce the internal interacting EMIs is emerging.

### SUMMARY OF THE INVENTION

Accordingly, it is an object of the present invention to provide a manufacturing method of a packaging structure of electronic components, by which the packaging structure can be protected from possible internal EMIs and thus performance of the electronics components can be substantially ensured.

In accordance with the present invention, the manufacturing method of a packaging structure of electronic components includes the following steps of: providing a substrate including a plurality of electronic components; covering the electronic components disposed on the substrate with a molding body; cutting out a plurality of pre-cut grooves on the molding body so as to define a plurality of molding units; forming an electromagnet barrier layer covering the molding units as well as the pre-cut grooves; and cutting along at least one of the pre-cut grooves deeply down to break the substrate so as to form separately a plurality of packaging structures of the electronic components.

By providing the manufacturing method of a packaging structure of electronic components according to the present invention, the manufacturing of an anti-EMI electronic module can be less complicated and make better the circuit design in miniaturization, high complicacy and reduced cost.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principals of the present invention.

FIG. 1 is a schematic drawing of a substrate having a plurality of electronic components to be mounted thereon in a preferred embodiment of the present invention.

FIG. 2 is a schematic drawing of a molding body covering the electronic components disposed on the substrate of FIG. 1.

FIG. 3 is a schematic drawing of a plurality of pre-cut grooves being cut out on the molding body of FIG. 2.

FIG. 4 is a schematic drawing of an electromagnet barrier layer covering molding units defined on the molding units by the pre-cut grooves of FIG. 3.

FIG. 5 is a schematic drawing of a molding surface body covering the electromagnet barrier layer of FIG. 4.

FIG. 6 is a schematic view showing separately the molding units by cutting along at least one of the pre-cut grooves of FIG. 5 deeply down to break the substrate.

FIG. 7 is a schematic view showing separately the molding units by cutting along at least one of the pre-cut grooves of FIG. 4 deeply down to break the substrate, according to another embodiment of the present method.

### DETAILED DESCRIPTION OF THE PREFERRED EMBODIMENTS

The present invention relates to a manufacturing method of a packaging structure of electronic components, and particularly relates to the manufacturing method that can provide a packaging structure having an effect on blocking the EMI. The following embodiments are included to provide a further understanding to the present invention. Persons having ordinary skill in the art should know the embodiments are for better explanation of the present invention and are not for limiting the present invention. Preferable embodiments of the present invention are as below.

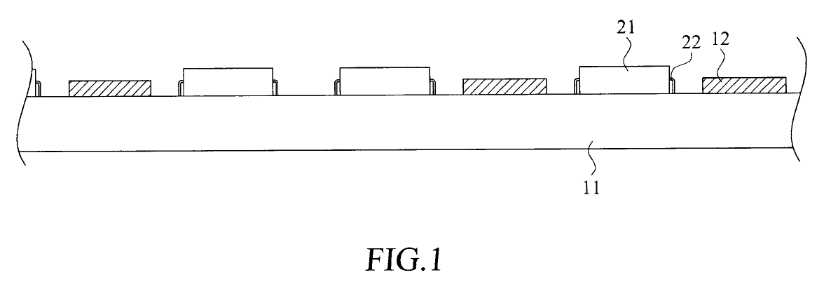

Referring to FIG. 1, a schematic drawing of a substrate 11 having thereon a plurality of electronic components 21 to be packaged according to a preferred embodiment of the present invention is shown. In the present invention, a manufacturing method of a packaging structure of electronic components 21 includes the steps of: (a) providing a substrate 11 having a plurality of electronic components 21 mounted thereon; (b) covering at least one of the electronic components 21 of the substrate 11 with a molding body; (c) cutting out a plurality of pre-cut grooves on the molding body so as to form a plurality of molding units, in which each of the molding units covers at least one of the electronic components 21; (d) forming an electromagnet barrier layer covering both the molding units and the pre-cut grooves; and (e) cutting along at least one of the pre-cut grooves 32 deeply down to break the substrate 11 so as to form separately a plurality of packaging structures of the electronic components.

The electronic components 21 are individually electrically connected to the substrate 11 by a plurality of respective welding leads 22, which the substrate 11 includes at least one ground conductor 12. Furthermore, the substrate 11 may include at least one ground via (not shown) electronically connected with the ground conductor 12.

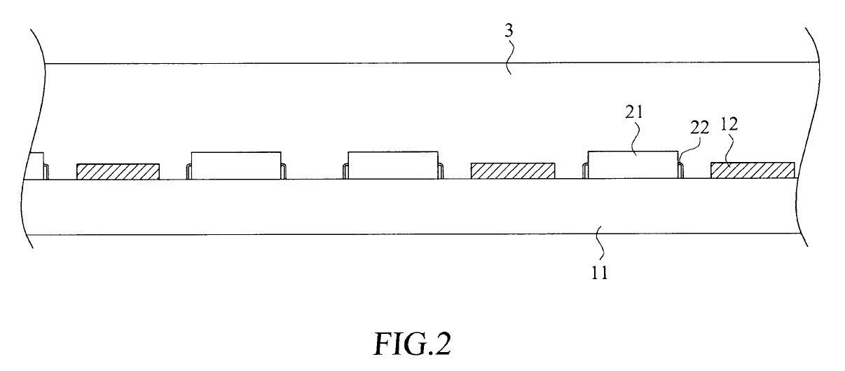

Referring now to FIG. 2, a schematic drawing of the molding body 3 covering the electronic components 21 disposed on the substrate 11 of FIG. 1 is shown. In the aforesaid step (b) of the present invention, in which the electronic components 21 disposed on the substrate 11 are covered by the molding body 3, a material of the molding body 3 can be a thermoset resin; preferably an epoxy resin.

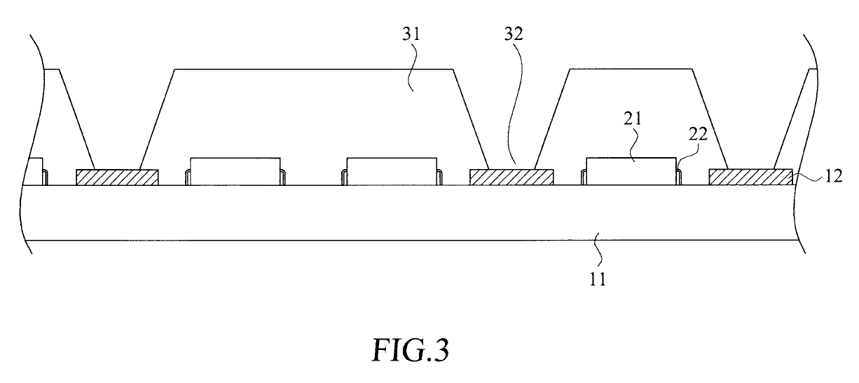

Referring to FIG. 3, a schematic drawing of a plurality of the pre-cut grooves 32 being cut out on the molding body 3 of FIG. 2 is shown. In the aforesaid step (c) of the present invention, a plurality of molding units 31 is formed by cutting out a plurality of the pre-cut grooves 32 on the molding body 3, in which as shown each of the molding units 31 may cover at least one electronic component 21. In the present invention, the grooves 32 can be pre-cut on the molding body 3 by a forming method selected from the group of a laser cutting, a sawing, and an etching.

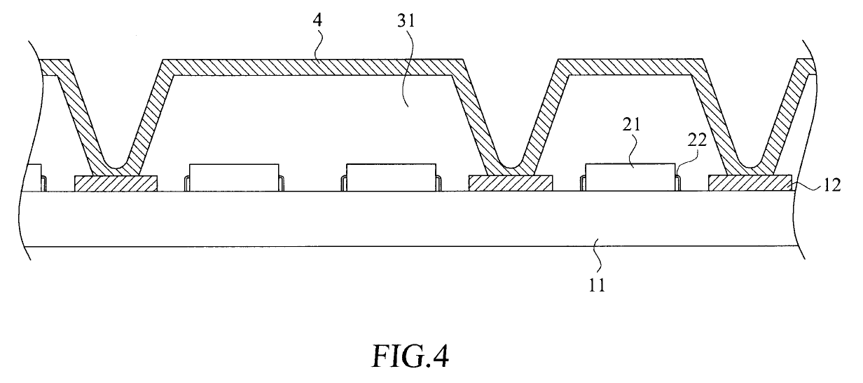

Referring to FIG. 4, a schematic drawing of the electromagnet barrier layer 4 covering the molding units 31 as well as the pre-cut grooves 32 of FIG. 3 is shown. In the aforesaid step (d) of the present invention, the electromagnet barrier layer 4 is formed to cover the molding units 31 and the pre-cut grooves 32, such that possible EMIs can be blocked in a molding-unit-wise. In the present invention, the electromagnet barrier layer 4 is used to mimic a plurality of mini conductive housings to shield respective electronic components 21 in individual molding units 31. The conductive material for the conductive housing can be a material selected from the group of a copper, a nickel, a gold, and an aluminum. The lamination method for forming the conductive barrier layer 4 on the molding body 3 can be a coating method selected from the group of inlaying, adhering, plating, painting, sputtering and vapor depositing. The conductive coating forming the conductive barrier layer 4 can include a conductive material selected from the group of a copper, a nickel, a gold and an aluminum.

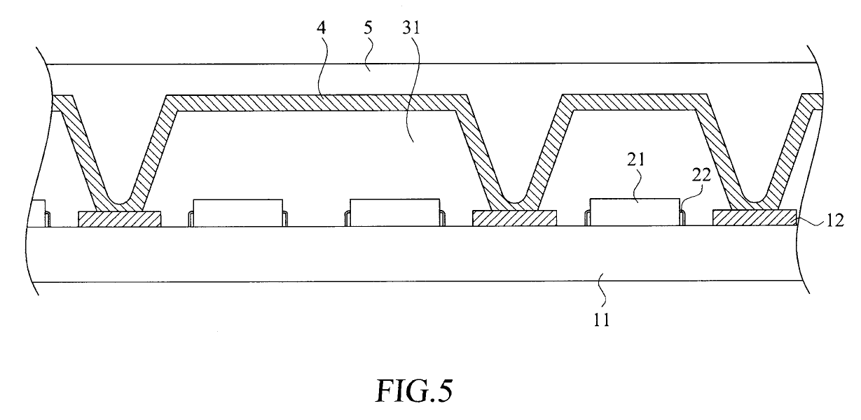

Referring now to FIG. 5, a schematic drawing of the molding surface body 5 covering the electromagnet barrier layer 4 of FIG. 4 is shown.

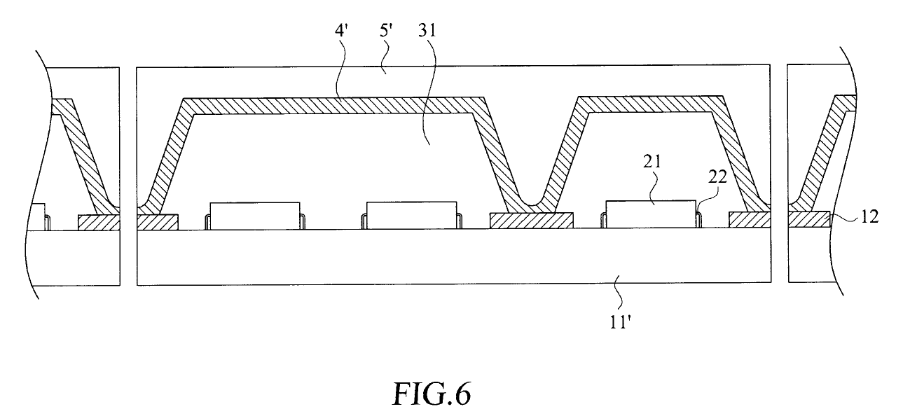

Referring to FIG. 6, a schematic view showing a plurality of the packaging structures separated by cutting along at least one of the pre-cut grooves 32 deeply down to break the substrate 11, i.e. by performing the aforesaid step (e), is shown.

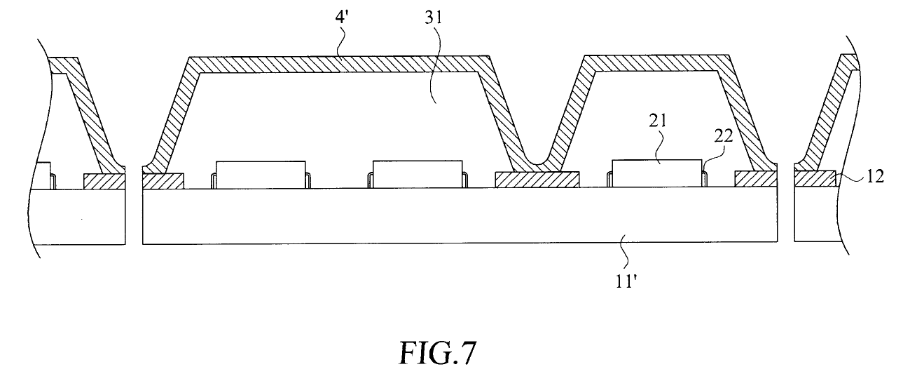

Referring now to FIG. 7, a schematic view showing a cutting result from performing a cutting along at least one of the pre-cut grooves 32 upon FIG. 4 is shown, according to another embodiment of the present invention. In the aspect, the separate structures based on the separate substrates 11′ are formed prior to the formation of the molding surface body 5. Then, the respective molding surface bodies 5 are respectively formed onto the separated blocks (including the corresponding substrates 11′) so as to form the packaging structures of the electronic components 21 as shown in FIG. 6.

Apparently, the difference between the foregoing two embodiments for forming the separate packaging structures lies in the ordering of the forming of the molding surface body 5 and the deep-cutting along the pre-cut grooves 32.

In the present invention, by either aforesaid formulation methods, the packaging structure of electronic components 21 includes the substrate 11′, at least one said electronic component 21 mounted on the substrate 11′ through respective leads 22 (that the electronic components 21 on the same substrate 11′ may belong to different molding units 31), and the electromagnet barrier layer 4′ for shielding the respective electronic components within the individual packaging structure, in which the substrate 11′ includes at least a ground area further having at least a ground lead 12. Furthermore, the substrate 11′ may include at least a ground via (not shown) electrically connected to the ground lead 12.

In the present invention, the electromagnet barrier layer 4′ covering the outer surface of the molding unit 31 may electrically connect the ground area.

Anyhow, in the present invention, the aforesaid molding surface body 5 is not a requirement for producing the anti-EMI packaging structures.

By providing the method of the present invention, it is obvious that the packaging structure of the electronic components can have the capability in blocking the EMI. In addition, by properly arranging the groove cutting and conductive barrier layering, the in situ EMI problem in the same substrate can be substantially resolved.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A manufacturing method of a packaging structure of electronic components, comprising the steps of:
(a) providing a substrate comprising a plurality of electronic components;
(b) covering at least one of the electronic components of the substrate with a molding body;
(c) cutting out a plurality of pre-cut grooves on the molding body to form a plurality of molding units, wherein each of the molding units covers at least one of the electronic components;
(d) forming an electromagnet barrier layer covering the molding units on the molding units and the pre-cut grooves; and
(e) cutting along at least one of the pre-cut grooves deeply down to break the substrate so as to form separately a plurality of packaging structures of the electronic components.

2. The manufacturing method of a packaging structure of electronic components according to claim 1, wherein the electronic components are electrically connected to the substrate by a plurality of welding leads.

3. The manufacturing method of a packaging structure of electronic components according to claim 1, wherein the substrate comprises at least one ground conductor.

4. The manufacturing method of a packaging structure of electronic components according to claim 3, wherein the substrate comprises at least one ground via electronically connected with the ground conductor.

5. The manufacturing method of a packaging structure of electronic components according to claim 1, wherein a material of the molding body comprises a thermoset resin.

6. The manufacturing method of a packaging structure of electronic components according to claim 5, wherein a material of the molding body comprises an epoxy resin.

7. The manufacturing method of a packaging structure of electronic components according to claim 1, wherein, in the step (c), the pre-cut grooves are pre-cut out on the molding body by means of a tool selected from the group of a laser blade and a resin glue saw blade.

8. The manufacturing method of a packaging structure of electronic components according to claim 1, wherein in step (c), the pre-cut grooves are pre-cut out on the molding body be an etching method.

9. The manufacturing method of a packaging structure of electronic components according to claim 1, wherein the electromagnet barrier layer comprises a conductive housing.

10. The manufacturing method of a packaging structure of electronic components according to claim 9, wherein the conductive housing comprises a conductive material selected from the group of a copper, a nickel, gold and aluminum.

11. The manufacturing method of a packaging structure of electronic components according to claim 9, wherein the conductive housing is fixed with the molding units by a joint method selected from the group of inlaying and adhering.

12. The manufacturing method of a packaging structure of electronic components according to claim 1, wherein the electromagnet barrier layer comprises a conductive coating.

13. The manufacturing method of a packaging structure of electronic components according to claim 12, wherein the conductive coating comprises a conductive material selected from the group of a copper, a nickel, gold, and aluminum.

14. The manufacturing method of a packaging structure of electronic components according to claim 12, wherein the conductive coating is formed by a method selected from the group of painting, adhering, plating, sputtering and vapor depositing.

15. The manufacturing method of a packaging structure of electronic components according to claim 1, further including a step (d1) poster to said step (d) of providing a molding surface body to cover the electromagnet barrier layer.
